(19) United States
(12) Patent Application Publication
(10) Pub. No.: US 2008/0157181 A1
(43) Pub. Date: Jul. 3, 2008

(54) NON-VOLATILE MEMORY DEVICE AND FABRICATION METHOD THEREOF

(75) Inventors: Jae Mun Kim, Seoul (KR); Jae Hyoung Koo, Kyeongki-do (KR); Dong Ho Lee, Kyeongki-do (KR); Kwon Hong, Kyeongki-do (KR); Woo Ri Jeong, Kyeongki-do (KR); Hee Soo Kim, Kyeongki-do (KR); Seung Woo Shin, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/964,287

(22) Filed: Dec. 26, 2007

(30) Foreign Application Priority Data
Dec. 28, 2006 (KR) 10-2006-136294
Nov. 5, 2007 (KR) 10-2007-111895

(51) Int. Cl. H01L 29/788; H01L 21/28

(52) U.S. Cl. 257/321; 438/591; 257/E29.304; 257/E21.179

(57) ABSTRACT

A non-volatile memory device and a fabrication method thereof. A high-k layer is formed between nitrogen-containing insulating layers. Accordingly, an interface reaction between an underlying oxide layer and the high-k insulating layer or between the oxide layer and a floating gate or a control gate can be prohibited and the electrical characteristics of the high-k layer can be improved, and a non-volatile memory device with high performance and high reliability can be fabricated.

### CROSS-REFERENCE TO RELATED APPLICATIONS

The priority of Korean patent application number 10-2006-136294 filed on Dec. 28, 2006, and Korean patent application number 10-2007-1111895 filed on Nov. 5, 2007, the entire respective disclosures of which are incorporated by reference herein, is claimed.

### BACKGROUND OF THE INVENTION

The invention relates to a non-volatile memory device and a fabrication method thereof and, more particularly, to a non-volatile memory device in which a high dielectric (high-k) layer with high performance and high reliability is formed.

In general, non-volatile memory devices retain data although power to the device is switched off. A unit cell of such a non-volatile memory device includes a tunnel insulating layer, a floating gate, a dielectric layer, and a control gate which are sequentially laminated over an active region of a semiconductor substrate. When voltage applied to a control gate electrode from the outside is coupled to the floating gate, data are stored in the unit cell. Thus, if it is desired to store data in a short period of time and at low program voltage, the ratio of voltage applied to the control gate electrode versus voltage induced to the floating gate must be great. The ratio of voltage applied to the control gate electrode versus voltage induced to the floating gate is called a coupling ratio. The coupling ratio can be represented as the ratio of capacitance of a gate pre-metal dielectric (PMD) layer with respect to the sum of capacitance of the tunnel insulating layer and the gate pre-metal dielectric (PMD) layer.

In prior art flash memory devices, an SiO₂/Si₃N₄/SiO₂ (“Oxide-Nitride-Oxide” or “ONO”) structure was generally used as the dielectric layer for isolating the floating gate and the control gate. In recent years, as devices have become more highly integrated, the thickness of the dielectric layer is decreased in order to secure the coupling ratio. Consequently, problems arise because reliability of the device is lowered due to an increase of the leakage current and a reduction in the charge retention characteristic.

In order to solve the problems, active research has been done on the development of a high-k layer, that is, a metal oxide having a relatively high dielectric constant when compared with SiO₂ or Si₃N₄ as a material that may replace the ONO dielectric layer. If the dielectric constant is high, the physical thickness necessary to produce the same capacitance can be extended. Accordingly, the leakage current characteristic can be improved compared with SiO₂ in an Equivalent Oxide Thickness (EOT). However, the high-k material reacts to upper and lower oxide layers and thus has a relatively low dielectric constant at the interface. Further, metal-silicate with a poor thin film characteristic is formed at each interface, lowering reliability of devices.

### BRIEF SUMMARY OF THE INVENTION

The invention is directed toward a non-volatile memory device and a fabrication method thereof, wherein a high-k layer including a high-k insulating layer is formed between oxide layers, and nitrogen-containing insulating layers are formed on and below the high-k insulating layers or over a floating gate and under the control gate, so an interface reaction between the oxide layer and the high-k insulating layer or between the oxide layer and the floating gate or the control gate can be prohibited and the electrical characteristics of the high-k layer can be improved.

A non-volatile memory device according to one embodiment of the invention includes a tunnel insulating layer formed on a semiconductor substrate, a floating gate formed on the tunnel insulating layer, a first nitrogen-containing insulating layer formed on the floating gate, a first insulating layer formed on the first nitrogen-containing insulating layer, a high-k insulating layer formed over the first insulating layer, a second insulating layer formed over the high-k insulating layer, a second nitrogen-containing insulating layer formed on the second insulating layer, and a control gate formed over the second nitrogen-containing insulating layer.

Each of the first and second nitrogen-containing insulating layers preferably comprises a silicon oxynitride (SiON) layer or a silicon nitride (Si₃N₄) layer.

Each of the first and second insulating layers is preferably formed to a thickness of 20 angstroms to 100 angstroms.

The high-k insulating layer is preferably formed from any one of (a) a single material layer, formed of any one high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BaₓSr₁₋ₓTiO₃ where x<1 (BST) and Pb[ZrₓTi₁₋ₓ]O₃ where 0<x<1 (PZT), (b) a mixed material layer, formed from material in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT is mixed with Al₂O₃, and (c) a laminated structure layer in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, is alternately laminated with Al₂O₃ material in a layer-by-layer concept. The mixed material layer is preferably formed by alternately laminating any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material to a thickness of 0.1 angstrom to 9.9 angstroms and then mixing any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material. The high-k insulating layer is preferably formed to a thickness of 20 angstroms to 150 angstroms.

The control gate is preferably formed from a polysilicon layer, or a metal layer made of metal material with a high work function. The metal layer preferably comprises Ti, TiN, TaN, Ta, HfN, ZrN, Mo, Pt, Ni, Au, Al, Cu, RuO₂, Ir or IrO₂.

Preferably, the device further comprises a third nitrogen-containing insulating layer between the high-k insulating layer and the first insulating layer, and a fourth nitrogen-containing insulating layer between the high-k insulating layer and the second insulating layer. Each of the third and fourth nitrogen-containing insulating layers preferably comprises a silicon oxynitride (SiON) layer or a silicon nitride (Si₃N₄) layer.

A sidewall oxide layer is preferably formed on a sidewall of a gate pattern comprising the tunnel insulating layer, the floating gate, the first and second nitrogen-containing insulating layers, the first and second insulating layers, the high-k insulating layer, and the control gate.

A non-volatile memory device according to another embodiment of the invention preferably comprises a tunnel insulating layer formed on a semiconductor substrate, a floating gate formed on the tunnel insulating layer, a first insulating layer formed over the floating gate, a first nitrogen-containing insulating layer formed on the first insulating layer, a high-k insulating layer formed over the first nitrogen-containing insulating layer, a second nitrogen-containing insulating layer formed on the second insulating layer, a second insulating layer the first insulating layer the second nitrogen-containing insulating layer, and a control gate formed over the second insulating layer.

Each of the first and second nitrogen-containing insulating layers preferably comprises a silicon oxynitride (SiON) layer or a silicon nitride (Si₃N₄) layer.

Each of the first and second insulating layers preferably comprises an aluminum oxide (Al₂O₃) layer or a dichlorosilane-High Temperature Oxide (DCS-HTO) layer. Each of the first and second insulating layers is preferably formed to a thickness of 20 angstroms to 100 angstroms.

The high-k insulating layer is preferably formed from any one of (a) a single material layer, formed of any one high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BaₓSr₁₋ₓTiO₃ where x<1 (BST) and Pb[ZrₓTi₁₋ₓ]O₃ where 0<x<1 (PZT), (b) a mixed material layer, formed from material in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT is mixed with Al₂O₃, and (c) a laminated structure layer in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, is alternately laminated with Al₂O₃ material in a layer-by-layer concept. The mixed material layer is preferably formed by alternately laminating any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material to a thickness of 0.1 angstrom to 9.9 angstroms and then mixing any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material. The high-k insulating layer is preferably formed to a thickness of 20 angstroms to 150 angstroms.

The control gate preferably comprises a polysilicon layer, or a metal layer made of metal material with a high work function. The metal layer preferably comprises any of Ti, TiN, TaN, Ta, HfN, ZrN, Mo, Pt, Ni, Au, Al, Cu, RuO₂, Ir or IrO₂.

The device preferably further comprises a third nitrogen-containing insulating layer between the floating gate and the first insulating layer, and a fourth nitrogen-containing insulating layer between the second insulating layer and the control gate. Each of the third and fourth nitrogen-containing insulating layers preferably comprises a silicon oxynitride (SiON) layer or a silicon nitride (Si₃N₄) layer.

A sidewall oxide layer is preferably formed on a sidewall of a gate pattern comprising the tunnel insulating layer, the floating gate, the first and second nitrogen-containing insulating layers, the first and second insulating layers, the high-k insulating layer, and the control gate.

A method of fabricating a non-volatile memory device according to another embodiment of the invention comprises providing a semiconductor substrate over which a tunnel insulating layer and a first conductive layer are formed, forming a first nitrogen-containing insulating layer formed on the first conductive layer, forming a first insulating layer on the first nitrogen-containing insulating layer, forming a high-k insulating layer over the first insulating layer, forming a second insulating layer over the high-k insulating layer, forming a second nitrogen-containing insulating layer on the second insulating layer, and forming a second conductive layer on the second nitrogen-containing insulating layer. The method of fabricating a non-volatile memory device preferably further includes forming a third nitrogen-containing insulating layer over the first insulating layer before the high-k insulating layer is formed, and forming a fourth nitrogen-containing insulating layer over the high-k insulating layer before the second insulating layer is formed.

Each of the first and second nitrogen-containing insulating layers is preferably formed using a Plasma Nitrification (PN) process or an Atomic Layer Deposition (ALD) method. The PN process is preferably performed using power of 0 kW to 5 kW and pressure of 0.1 torr to 1 torr at a temperature in the range of 300 degrees Celsius to 600 degrees Celsius. The PN process is preferably performed in mixed gas atmosphere of an Ar gas and a N₂ gas. The ALD method is preferably performed at a temperature in the range of 200 degrees Celsius to 500 degrees Celsius.

Each of the third and fourth nitrogen-containing insulating layers is preferably formed using a PN process or an ALD method.

Each of the first and second insulating layers is preferably formed from an aluminum oxide (Al₂O₃) layer. The aluminum oxide (Al₂O₃) layer is preferably formed using an ALD method employing a metal organic source or a halide source as an aluminum precursor. The ALD method is preferably performed at a temperature in the range of 300 degrees Celsius to 500 degrees Celsius. The ALD method is preferably performed using O₂, H₂O, or O₃ as a reactive gas. The ALD method is preferably performed using a N₂ gas or an Ar gas as a purge gas.

Each of the first and second insulating layers is preferably formed to a thickness of 20 angstroms to 100 angstroms.

The high-k insulating layer is preferably formed from any one of (a) a single material layer, formed of any one high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BaₓSr₁₋ₓTiO₃ where x<1 (BST) and Pb[ZrₓTi₁₋ₓ]O₃ where 0<x<1 (PZT), (b) a mixed material layer, formed from material in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT is mixed with Al₂O₃, and (c) a laminated structure layer in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, is alternately laminated with Al₂O₃ material in a layer-by-layer concept. The mixed material layer is preferably formed by alternately laminating any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material to a thickness of 0.1 angstrom to 9.9 angstroms and then mixing any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material. The high-k insulating layer is preferably formed to a thickness of 20 angstroms to 150 angstroms.

The high-k insulating layer is preferably formed using an ALD method employing a metal organic source or a halide source as a metal precursor. The ALD method is performed at a temperature in the range of 200 degrees Celsius to 500 degrees Celsius. The ALD method is preferably performed using O₂, H₂O, or O₃ as a reactive gas. The ALD method is preferably performed using a N₂ gas or an Ar gas as a purge gas.

The high-k insulating layer is preferably formed to a thickness of 20 angstroms to 150 angstroms.

The second conductive layer is preferably formed from a polysilicon layer, or a metal layer made of metal material with a high work function. The metal layer is preferably formed from Ti, TiN, TaN, Ta, HfN, ZrN, Mo, Pt, Ni, Au, Al, Cu, RuO₂, Ir or IrO₂. The second conductive layer preferably further comprises a tungsten nitride (WN) layer and a tungsten (W) layer formed over the metal layer. Each of the metal layer, the tungsten nitride (WN) layer, and the tungsten (W) layer is preferably formed using a Chemical Vapor Deposition (CVD) method, a Physical Vapor Deposition (PVD) method or an ALD method. After the tungsten nitride (WN) layer is formed, a thermal treatment process is preferably further performed. The thermal treatment process is preferably performed using a Rapid Thermal Process (RTP) process in a temperature range of 500 degrees Celsius to 900 degrees Celsius in N₂ atmosphere.

A method of fabricating a non-volatile memory device according to another embodiment of the invention includes providing a semiconductor substrate over which a tunnel insulating layer and a first conductive layer are formed, forming a first insulating layer over the first conductive layer, forming a first nitrogen-containing insulating layer on the first insulating layer, forming a high-k insulating layer over the first nitrogen-containing insulating layer, forming a second nitrogen-containing insulating layer on the high-k insulating layer, forming a second insulating layer over the second nitrogen-containing insulating layer, and forming a second conductive layer over the second insulating layer. A method of fabricating a non-volatile memory device preferably further includes forming a third nitrogen-containing insulating layer over the first conductive layer before the first insulating layer is formed, and forming a fourth nitrogen-containing insulating layer on the second insulating layer before the second conductive layer is formed.

Each of the first and second nitrogen-containing insulating layers is preferably formed using a Plasma Nitrification (PN) process or an Atomic Layer Deposition (ALD) method.

Each of the third and fourth nitrogen-containing insulating layers is preferably formed using a PN process or an ALD method. The PN process is preferably performed using power of 0 kW to 5 kW and pressure of 0.1 torr to 1 torr at a temperature in the range of 300 degrees Celsius to 600 degrees Celsius. The PN process is preferably performed in mixed gas atmosphere of an Ar gas and a N₂ gas. The ALD method is preferably performed at a temperature in the range of 200 degrees Celsius to 500 degrees Celsius.

Each of the first and second insulating layers is preferably formed from a dichlorosilane-High Temperature Oxide (DCS-HTO) layer. The DCS-HTO layer is preferably formed using a Low Pressure Chemical Vapor Deposition (LPCVD) method. The LPCVD is preferably performed at a temperature in the range of 600 degrees Celsius to 900 degrees Celsius.

Each of the first and second insulating layers is preferably formed to a thickness of 20 angstroms to 100 angstroms.

The high-k insulating layer is preferably formed from any one of (a) a single material layer, formed of any one high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BaₓSr₁₋ₓTiO₃ where x<1 (BST) and Pb[ZrₓTi₁₋ₓ]O₃ where 0<x<1 (PZT), (b) a mixed material layer, formed from material in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT is mixed with Al₂O₃, and (c) a laminated structure layer in which any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, is alternately laminated with Al₂O₃ material in a layer-by-layer concept. The mixed material layer is preferably formed by alternately laminating any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material to a thickness of 0.1 angstrom to 9.9 angstroms and then mixing any one material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material. The high-k insulating layer is preferably formed to a thickness of 20 angstroms to 150 angstroms.

The high-k insulating layer is preferably formed using an ALD method employing a metal organic source or a halide source as a metal precursor. The ALD method is preferably performed at a temperature in the range of 200 degrees Celsius to 500 degrees Celsius. The ALD method is preferably performed using O₂, H₂O, or O₃ as a reactive gas. The ALD method is preferably performed using a N₂ gas or an Ar gas as a purge gas.

The high-k insulating layer is preferably formed to a thickness of 20 angstroms to 150 angstroms.

The second conductive layer is preferably formed from a polysilicon layer, or a metal layer made of metal material with a high work function. The metal layer is preferably formed from Ti, TiN, TaN, Ta, HfN, ZrN, Mo, Pt, Ni, Au, Al, Cu, RuO₂, Ir or IrO₂. The second conductive layer preferably further comprises a tungsten nitride (WN) layer and a tungsten (W) layer formed over the metal layer. Each of the metal layer, the tungsten nitride (WN) layer, and the tungsten (W) layer is preferably formed using a CVD method, a Physical Vapor Deposition (PVD) method, or an ALD method. After the tungsten nitride (WN) layer is formed, a thermal treatment process is preferably further performed. The thermal treatment process is preferably performed using a Rapid Thermal Process (RTP) process at a temperature in the range of 500 degrees to 900 degrees Celsius in N₂ atmosphere.

A thermal treatment process is preferably further performed between the formation of the second nitrogen-containing insulating layer and the formation of the second conductive layer. The thermal treatment process is preferably performed using an RTP process at a temperature in the range of 700 degrees Celsius to 1000 degrees Celsius in N₂ or O₂ atmosphere.

### BRIEF DESCRIPTION OF THE DRAWINGS

FIGS. 1a to 1k are sectional views illustrating a method of fabricating a non-volatile memory device according to an embodiment of the invention.

### DESCRIPTION OF SPECIFIC EMBODIMENTS

A specific embodiment according to the invention is described below with reference to the accompanying drawings.

However, the invention is not limited to the disclosed embodiment, but may be implemented in various manners. The embodiment is provided to complete the disclosure of the invention and to allow those having ordinary skill in the art to understand the scope of the present invention. The invention is defined by the category of the claims.

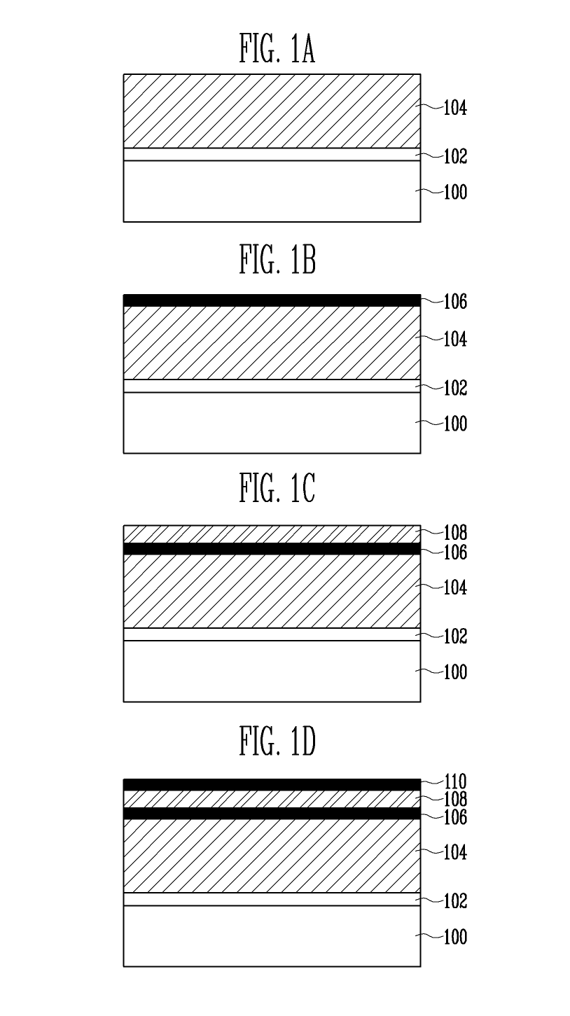

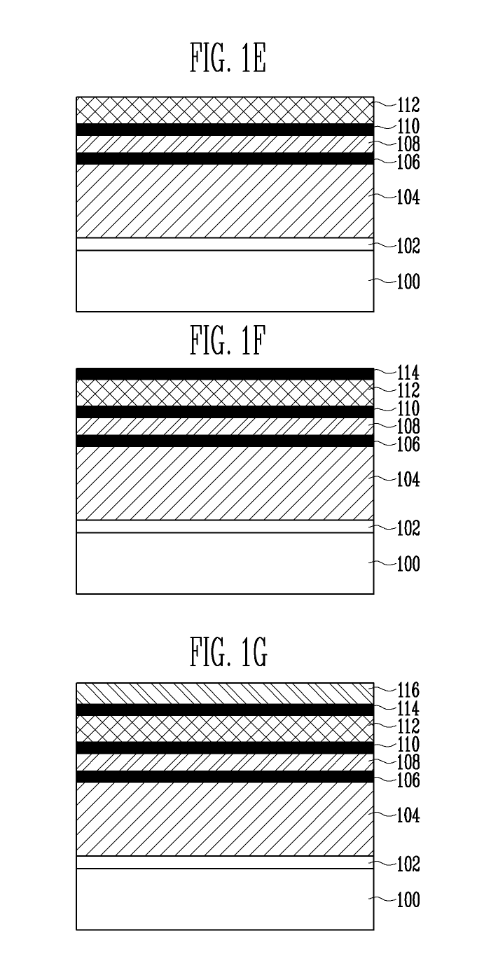

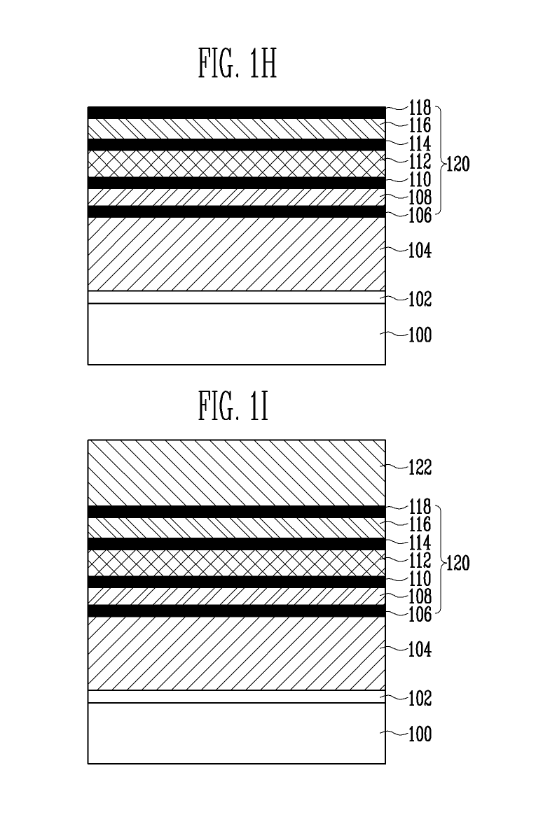

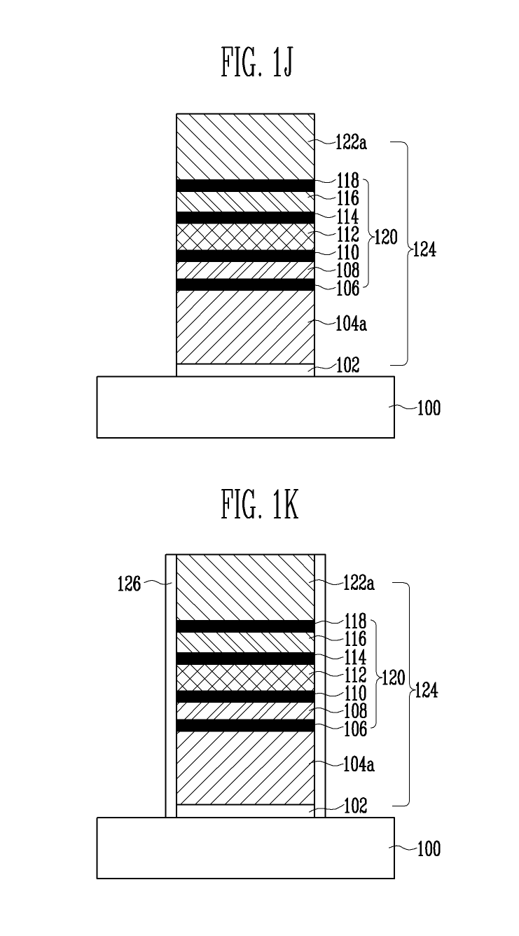

FIGS. 1a to 1k are sectional views illustrating a method of fabricating a non-volatile memory device according to an embodiment of the invention.

Referring to FIG. 1a, there is provided a semiconductor substrate 100 over which a tunnel insulating layer 102 and a first conductive layer 104 are formed. A well region (not shown) is formed in the semiconductor substrate 100. The well region may have a triple structure. The well region may be formed by forming a screen oxide layer (not shown) on the semiconductor substrate 100 and then performing a well ion implantation process and a threshold voltage ion implantation process.

After the screen oxide layer is removed, a tunnel insulating layer 102 is formed over the semiconductor substrate 100 in which the well region is formed. The tunnel insulating layer 102 may be formed from a silicon oxide (SiO₂) layer using an oxidation process. The first conductive layer 104 is formed to form a floating gate of a flash memory device and may be formed from a polysilicon layer. The first conductive layer 104 may be formed using a Chemical Vapor Deposition (CVD) method, such as a Plasma-Enhanced CVD (PECVD) method or a Low Pressure CVD (LPCVD) method. The first conductive layer 104 is then patterned in one direction (a bit line direction) using an etch process employing a mask (not shown). In order to prevent the first conductive layer 104 from being lost in the process of pattering the first conductive layer 104, a hard mask layer (not shown) may be further formed on the first conductive layer 104. The hard mask layer is removed after pattering the first conductive layer 104. The mask may include a photoresist pattern. The photoresist pattern may be formed by coating a photoresist and then pattering it through exposure and development.

Referring to FIG. 1b, a first nitrogen-containing insulating layer 106 is formed on the first conductive layer 104. The first nitrogen-containing insulating layer 106 may comprise any suitable insulating layer containing nitrogen (N). The first nitrogen-containing insulating layer 106 may be formed by performing a nitrification process, such as a Plasma Nitrification (PN) process, on the surface of the first conductive layer 106. Specifically, the PN process may be performed using the power of 0 kW to 5 kW, the pressure of 0.1 torr to 1 torr at a temperature in the range of 300 degrees Celsius to 600 degrees Celsius in a mixed gas atmosphere of an Ar gas and a N₂ gas.

Alternatively, the first nitrogen-containing insulating layer 106 may also be formed by a deposition method. At this time, the first nitrogen-containing insulating layer 106 may be formed using an Atomic Layer Deposition (ALD) method with excellent step coverage of about 99% at a temperature in the range of 200 degrees to 500 degrees Celsius. The first nitrogen-containing insulating layer 106 may be formed using a silicon oxynitride (SiON) layer or a silicon nitride (Si₃N₄) layer. If the first nitrogen-containing insulating layer 106 is formed using the ALD method as described above, it is advantageous in that the film quality can be improved compared with when it is formed using the PN process and an excellent step coverage of almost 100% can be secured.

As described above, if the first nitrogen-containing insulating layer 106 is formed on the first conductive layer 104, an oxide layer, which is used as an underlying layer of a high-k layer to be subsequently formed, is not directly brought in contact with the first conductive layer 104. Thus, since a reaction at the interface of the first conductive layer 104 and the oxide layer is prohibited, a bird's beak phenomenon in which the thickness of the oxide layer is increased at both edges of the first conductive layer 104 can be prevented although an oxidization process is performed on a gate sidewall in a subsequent process.

Referring to FIG. 1c, a first insulating layer 108 is formed on the first nitrogen-containing insulating layer 106. The first insulating layer 108 is used as the underlying layer of the high-k layer, and may be formed from an oxide layer. For example, the first insulating layer 108 may be formed from a dichlorosilane-High Temperature Oxide (DCS-HTO) layer with an excellent step coverage characteristic or an aluminum oxide (Al₂O₃) layer for prohibiting a reaction at the interface when it is brought in contact with a polysilicon layer or high-k material. At this time, the first insulating layer 108 may be formed to a thickness of 20 angstrom to 100 angstrom using a LPCVD method at a temperature in the range of 600 degrees Celsius to 900 degrees Celsius.

On the other hand, in the event that the first insulating layer 108 is formed from the aluminum oxide (Al₂O₃) layer, it is formed using an ALD method. The ALD method for forming the aluminum oxide (Al₂O₃) layer may be performed by separately injecting a source and a reactive gas and inserting a purge process between the processes of injecting the source and the reactive gas by employing an adsorption and desorption reaction. To this end, the ALD method may include supplying a metal organic source or a halide source, such as Trimethyl Aluminum (Al(CH₃)₃) (hereinafter, referred to as “TMA”), as an aluminum precursor, supplying and purging an N₂ gas or an Ar gas, and then supplying and purging a reactive gas such as O₂, H₂O, or O₃, at a temperature in the range of 300 degrees Celsius to 500 degrees Celsius. At this time, the first insulating layer 108 may be formed to a thickness of 20 angstroms to 100 angstroms.

If the first insulating layer 108 is formed from the aluminum oxide (Al₂O₃) layer as described above, even though the first insulating layer 108 used as the underlying layer of the high-k layer is directly brought in contact with a high-k insulating layer to be formed subsequently, the occurrence of a metal-silicate layer with a poor thin film characteristic at the interface of the first insulating layer 108 and the high-k insulating layer due to a reaction of a metal source of the high-k insulating layer with a silicon (Si) source and an oxygen (O₂) source of the first insulating layer 108 can be prevented. Accordingly, the dielectric constant of the high-k insulating layer can be prevented from lowering. In this connection, to form the first insulating layer 108 using the aluminum oxide (Al₂O₃) layer rather than the DCS-HTO layer is more advantageous to maintain the thin film characteristic of the high-k insulating layer itself. If the aluminum oxide (Al₂O₃) layer is formed using the ALD method, the film quality can be improved and excellent step coverage of almost 100% can be secured.

Referring to FIG. 1d, a second nitrogen-containing insulating layer 110 is formed on the first insulating layer 108. The second nitrogen-containing insulating layer 110 functions to prevent the dielectric constant of the high-k insulating layer from lowering due to a reaction at the interface of the high-k insulating layer and the first insulating layer 108 because the high-k insulating layer is directly brought in contact with the surface of the first insulating layer 108. The second nitrogen-containing insulating layer 110 may be formed from any kinds of insulating layers containing nitrogen (N).

The second nitrogen-containing insulating layer 110 may be formed by performing a nitrification process on the surface of the first insulating layer 108. At this time, the second nitrogen-containing insulating layer 110 may be formed using a PN process. Specifically, the PN process may be performed using the power of 0 kW to 5 kW and the pressure of 0.1 torr to 1 torr at a temperature in the range of 300 degrees Celsius to 600 degrees Celsius in mixed gas atmosphere of an Ar gas and a N₂ gas. In the event that the first insulating layer 108 is formed from the DCS-HTO layer, the second nitrogen-containing insulating layer 110 may be formed from a silicon oxynitride (SiON) layer or a silicon nitride (Si₃N₄) layer.

Alternatively, the second nitrogen-containing insulating layer 110 may also be formed from a silicon nitride (Si₃N₄) layer using an ALD method at a temperature in the range of 200 to 500 degrees Celsius. If the second nitrogen-containing insulating layer 110 is formed using the ALD method as described above, it is advantageous in that the film quality can be improved compared with when the second nitrogen-containing insulating layer 110 is formed using the PN process and an excellent step coverage of almost 100% can be obtained.

Referring to FIG. 1e, high-k material is deposited on the second nitrogen-containing insulating layer 110 in order to form a high-k insulating layer 112. The high-k material refers to material having a dielectric constant higher than 3.9, which is the dielectric constant of SiO₂, and may include Al₂O₃, HfO₂, ZrO₂, SiON, La₂O₃, Y₂O₃, TiO₂, CeO₂, N₂O₃, Ta₂O₅, BaTiO₃, SrTiO₃, BST, PZT, and so on.

The high-k insulating layer 112 according to an embodiment of the present invention may be formed from any one of a single material layer, formed of any one high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, a mixed material layer, formed from material in which any one selected from the group consisting of HfO₂, ZrO₂, SiON, La₂O₃, Y₂O₃, TiO₂, CeO₂, N₂O₃, Ta₂O₅, BaTiO₃, SrTiO₃, BST and PZT, and Al₂O₃ material are mixed, and a laminated structure layer in which any one selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and Al₂O₃ material are alternately laminated in a layer-by-layer concept. The high-k insulating layer 112 is preferably formed to a thickness of 20 angstroms to 150 angstroms at a temperature in the range of 200 degrees Celsius to 500 degrees Celsius using an ALD method.

Specifically, the high-k insulating layer 112 is preferably formed using a metal organic source or a halide source as a metal precursor of the high-k material and O₂, H₂O or O₃ as a reactive gas. For this purpose, the ALD method for forming the high-k insulating layer 112 formed of the high-k material may include supplying the metal organic source or the halide source as the metal precursor, supplying and purging the N₂ gas or the Ar gas, and then supplying and purging a reactive gas such as O₂, H₂O, or O₃, at a temperature in the range of 200 degrees Celsius to 500 degrees Celsius. If purge is performed using the N₂ gas or the Ar gas, the high-k insulating layer 112 having an excellent film quality can be prevented since a CVD reaction is prevented.

In particular, the mixed material layer is preferably formed by alternately laminating any one selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT, and the Al₂O₃ material through an ALD method, but depositing each layer to a thin thickness of 10 angstrom or less (0.1 angstrom to 9.9 angstroms) per unit cycle. In this case, the respective layers are formed discontinuously and therefore formed as the mixed material layer. For example, the mixed material layer may include a hafnium-aluminum oxide (HfAlO) layer in which HfO₂ material and Al₂O₃ material are mixed, a zirconium-aluminum oxide (ZrAlO) layer in which ZrO₂ material and Al₂O₃ material are mixed, and so on.

Meanwhile, the laminated structure layer may have an independent structure of a film fashion in which the respective layers are continuous by depositing each layer to a thickness of 10 angstroms or more so that they are laminated in a layer-by-layer form.

As described above, in an embodiment of the present invention, the high-k insulating layer 112 is formed from the high-k material. Accordingly, there are advantages in that capacitance can be increased, and therefore the coupling ratio can be increased and the leakage current leakage current can be reduced. Since the high-k insulating layer 112 is formed thinly, the dielectric constant of the high-k insulating layer 112 can be further improved by forming the high-k insulating layer 112 of an amorphous state.

In particular, a variety of compositions can be obtained through control of the cycle number by deposing the high-k insulating layer 112 using the ALD method. Accordingly, electrical characteristics of devices, such as the dielectric constant, the leakage current, breakdown voltage, the flatband voltage, and cycling, can be improved. Further, not only the film quality can be improved significantly, but also step coverage can be improved and an inter-cell interference phenomenon can be reduced.

Furthermore, since the high-k insulating layer 112 is formed at a low temperature in the range of 200 degrees Celsius to 500 degrees Celsius, thermal budget with respect to the underlying tunnel insulating layer 102 can be reduced and reliability of devices can be improved.

Referring to FIG. 1f, a third nitrogen-containing insulating layer 114 is formed on the high-k insulating layer 112. The third nitrogen-containing insulating layer 114 functions to prevent the dielectric constant of the high-k insulating layer 112 from lowering due to a reaction at the interface of an oxide layer and the high-k insulating layer 112 because the oxide layer is directly brought in contact with the surface of the high-k insulating layer 112. The third nitrogen-containing insulating layer 114 may be formed from any kinds of insulating layers containing nitrogen (N).

The third nitrogen-containing insulating layer 114 is preferably formed by performing a nitrification process on the surface of the high-k insulating layer 112. The third nitrogen-containing insulating layer 114 may be formed using a PN process. Specifically, the PN process may be performed using the power of 0 kW to 5 kW and the pressure of 0.1 torr to 1 torr at a temperature in the range of 300 degrees Celsius to 600 degrees Celsius in a mixed gas atmosphere of an Ar gas and a N₂ gas.

Alternatively, the third nitrogen-containing insulating layer 114 may be formed from a silicon nitride (Si₃N₄) layer using an ALD method at a temperature in the range of 200 degrees Celsius to 500 degrees Celsius. If the third nitrogen-containing insulating layer 114 is formed using the ALD method as described above, it is advantageous in that the film quality can be improved compared with when the third nitrogen-containing insulating layer 114 is formed using the PN process and an excellent step coverage of almost 100% can be obtained.

Referring to FIG. 1g, a second insulating layer 116 is formed on the third nitrogen-containing insulating layer 114. The second insulating layer 116 is used as an upper layer of a high-k layer. The second insulating layer 116 may be formed from a DCS-HTO layer with an excellent step coverage characteristic, or an aluminum oxide (Al₂O₃) layer in order to prohibit a reaction at the interface when a polysilicon layer for a control gate is brought in contact with high-k material.

When the second insulating layer 116 is formed from the DCS-HTO layer, the second insulating layer 116 may be formed using a LPCVD method to a thickness of 20 angstrom to 100 angstrom at a temperature in the range of 600 degrees to 900 degrees Celsius. On the other hand, when the second insulating layer 116 is formed from the aluminum oxide (Al₂O₃) layer, the second insulating layer 116 may be formed using an ALD method. To this end, the ALD method may include supplying a metal organic source or a halide source, such as TMA, as an aluminum precursor, supplying and purging a N₂ gas or an Ar gas, and then supplying and purging a reactive gas, such as O₂, H₂O, or O₃, at a temperature in the range of 300 degrees Celsius to 500 degrees Celsius. At this time, the second insulating layer 116 is preferably formed to a thickness of 20 angstroms to 100 angstrom.

If the second insulating layer 116 is formed from the aluminum oxide (Al₂O₃) layer as described above, even though the second insulating layer 116 used as the upper layer of the high-k layer is directly brought in contact with the high-k insulating layer 112, the occurrence of a metal-silicate layer with a poor thin film characteristic at the interface of the second insulating layer 116 and the high-k insulating layer 112 due to a reaction of the metal source of the high-k insulating layer with the silicon (Si) source and the oxygen (O₂) source of the second insulating layer 116 can be prevented.

Further, if the second insulating layer 116 is formed from the aluminum oxide (Al₂O₃) layer, a reaction at the interface of the polysilicon layer and the second insulating layer 116 is prohibited although the polysilicon layer for the control gate (not shown) is directly brought in contact with the second insulating layer 116. Accordingly, even though an oxidization process is performed on a gate sidewall in a subsequent process, a bird's beak phenomenon in which the thickness of the oxide layer is increased at both edges of the polysilicon layer for the control gate can be prevented. Thus, to form the second insulating layer 116 using the aluminum oxide (Al₂O₃) layer rather than the DCS-HTO layer is more advantageous to maintain the thin film characteristic of the high-k insulating layer 112 itself and prohibit the bird's beak phenomenon of the polysilicon layer. If the aluminum oxide (Al₂O₃) layer is formed using the ALD method, the film quality can be improved and an excellent step coverage of almost 100% can be obtained.

Referring to FIG. 1h, a fourth nitrogen-containing insulating layer 118 is formed on the second insulating layer 116. The fourth nitrogen-containing insulating layer 118 may include any kinds of insulating layers containing nitrogen (N). The fourth nitrogen-containing insulating layer 118 may be formed by performing a nitrification process on the surface of the second insulating layer 116. The fourth nitrogen-containing insulating layer 118 may be formed using a PN process. Specifically, the PN process may be performed using the power of 0 kW to 5 kW and the pressure of 0.1 torr to 1 torr at a temperature in the range of 300 to 600 degrees Celsius in a mixed gas atmosphere of an Ar gas and a N₂ gas. Accordingly, the fourth nitrogen-containing insulating layer 118 formed from the silicon oxynitride (SiON) layer, the silicon nitride (Si₃N₄) layer or the like may be formed.

Alternatively, the fourth nitrogen-containing insulating layer 118 may be formed from a silicon nitride (Si₃N₄) layer using an ALD method at a temperature in the range of 200 degrees Celsius to 500 degrees Celsius. If the fourth nitrogen-containing insulating layer 118 is formed using the ALD method as described above, it is advantageous in that the film quality can be improved compared with when the fourth nitrogen-containing insulating layer 118 is formed using the PN process and an excellent step coverage of almost 100% can be obtained.

Meanwhile, after the fourth nitrogen-containing insulating layer 118 is formed, a Rapid Thermal Processing (RTP) process may be further performed in order to further densify the layer. The RTP process is preferably performed at a temperature in the range of 700 degrees Celsius to 1000 degrees Celsius in an N₂ or O₂ atmosphere.

If the fourth nitrogen-containing insulating layer 118 is formed on the second insulating layer 116 as described above, the polysilicon layer for the control gate to be formed subsequently is not directly brought in contact with the second insulating layer 116, so a reaction at the interface of the second insulating layer 116 and the polysilicon layer for the control gate can be prohibited. Accordingly, even though an oxidization process is performed on a gate sidewall in a subsequent process, a bird's beak phenomenon in which the thickness of the oxide layer is increased at both edges of the polysilicon layer for the control gate can be prevented.

At this time, the first insulating layer 108, the high-k insulating layer 112 and the second insulating layer 116, and the first to fourth nitrogen-containing insulating layers 106, 110, 114, and 118, which are formed between the first insulating layer 108, the high-k insulating layer 112 and the second insulating layer 116, and on or below the first insulating layer 108, the high-k insulating layer 112 and the second insulating layer 116, constitute a high-k layer 120.

As described above, in accordance with the disclosed embodiment of the invention, the high-k layer 120 includes the high-k insulating layer 112 formed from the high-k material using the ALD method. Accordingly, there are advantages in that capacitance can be increased while reducing the thickness of the high-k layer 120 and, therefore, the coupling ratio can be increased and the leakage current can be reduced.

Further, since the high-k insulating layer 112 is formed using the ALD method, film characteristics such as the dielectric constant, the leakage current, and breakdown voltage can be improved. Thus, not only the film quality can be improved, but also step coverage can be improved and an inter-cell interference phenomenon can be reduced. Consequently, devices with high performance and high reliability can be fabricated.

In addition, as described above, the first and second insulating layers 108, 116 of the high-k layer 120 are formed from the aluminum oxide (Al₂O₃) layer. Therefore, although the first insulating layer 108 is directly brought in contact with the high-k insulating layer 112 or the polysilicon layer 104 for the floating gate, or the second insulating layer 116 is directly brought in contact with the high-k insulating layer 112 or the polysilicon layer for the control gate to be formed subsequently, a reaction at the interface of the first insulating layer 108 and the high-k insulating layer 112 or the polysilicon layer 104, or the second insulating layer 116 and the high-k insulating layer 112 or the polysilicon layer can be prohibited. Accordingly, even though an oxidization process is performed on a gate sidewall in a subsequent process, a bird's beak phenomenon in which the thickness of the oxide layer is increased at both edges of the polysilicon layer for the floating gate or the polysilicon layer for the control gate can be prevented.

Incidentally, the first to fourth nitrogen-containing insulating layers 106, 110, 114, and 118 are formed between the layers 104, 108, 112, and 116. A reaction at the interface of the respective layers can be prohibited and, therefore, the high-k layer 120 whose dielectric constant is prevented from lowering can be formed. In particular, in the event that the first to fourth nitrogen-containing insulating layers 106, 110, 114, and 118, the first and second insulating layers 108, 116, and the high-k insulating layer 112 are formed using the ALD method, the respective layers are formed in-situ. Accordingly, since the Turn Around Time (TAT) can be shortened, productivity can be enhanced and investment expenses to other equipment can be saved.

In the present invention, for convenience of description, it has been described that the first to fourth nitrogen-containing insulating layers 106, 110, 114, and 118 are formed between or on the respective layers 104, 108, 112, and 116. However, it is to be noted that the second and third nitrogen-containing insulating layers 110, 114 or the first and fourth nitrogen-containing insulating layers 106, 118 may be omitted according to the characteristics of the first and second insulating layers 108, 116.

Referring to FIG. 1i, a second conductive layer 122 is formed on the fourth nitrogen-containing insulating layer 118. The second conductive layer 122 is used as the control gate of the flash memory device. The second conductive layer 122 may be formed from a polysilicon layer, or a metal layer made of metal material with a high work function. The metal layer preferably includes Ti, TiN, TaN, Ta, HfN, ZrN, Mo, Pt, Ni, Au, Al, Cu, RuO₂, Ir, or IrO₂.

As described above, if the second conductive layer 122 is formed from the metal layer made of metal material with a high work function, a reaction at the interface can be prohibited and the leakage current can be reduced although the second conductive layer 122 is directly brought in contact with the second insulating layer 116.

Meanwhile, in the event that the second conductive layer 122 is formed from the metal layer made of metal material with a high work function, a tungsten nitride (WN) layer and a tungsten (W) layer may be further formed over the metal layer in order to lower resistance of the second conductive layer 122. The tungsten nitride (WN) layer is used as a diffusion barrier for preventing the diffusion of the tungsten (W). Each of the metal layer, the tungsten nitride (WN) layer, and the tungsten (W) layer may be formed using a CVD method, a PVD method or an ALD method. If the ALD method is employed, each of the metal layer, the tungsten nitride (WN) layer, and the tungsten (W) layer may be formed using an in-situ process with the high-k layer 120 formed using the ALD method, so productivity can be improved.

After the tungsten nitride (WN) layer is formed, a RTP process may be further carried out. The RTP process may be performed at a temperature in the range of 500 degrees Celsius to 900 degrees Celsius in N₂ atmosphere.

Referring to FIG. 1j, a typical etch process employing a mask (not shown) is performed in order to pattern the second conductive layer 122, the high-k layer 120, the first conductive layer 104, and the tunnel insulating layer 102. Such pattering is performed in a direction (a word line direction) to cross the first conductive layer 104 patterned in one direction. Accordingly, a floating gate 104a comprised of the first conductive layer 104 and a control gate 122a comprised of the second conductive layer 122 are formed. At this time, the tunnel insulating layer 102, the floating gate 104a, the high-k layer 120, and the control gate 122a constitute a gate pattern 124.

Referring to FIG. 1k, in order to cure damage generated at the gate pattern 124 due to the etch process for forming the gate pattern 124, a sidewall oxidization process is performed. The sidewalls of the gate pattern 124 are oxidized through the sidewall oxidization process, so that an etch damage layer leads to a sidewall oxide layer 126. In the present invention, as described above, the first nitrogen-containing insulating layer 106 is formed between the floating gate 104a and the first insulating layer 108 and the fourth nitrogen-containing insulating layer 118 is formed between the control gate 122a and the second insulating layer 116, or the first and second insulating layers 108, 116 are formed from the aluminum oxide (Al₂O₃) layer. Accordingly, a reaction at the interface of the respective layers can be prohibited. Thus, although the sidewall oxidization process is implemented, a bird's beak phenomenon at both edges of the floating gate 104a and the control gate 126 can be prevented.

The invention has at least the following advantages.

First, the high-k layer includes a unique insulating layer comprised of high-k material. Thus, the coupling ratio can be increased and the leakage current can be reduced.

Second, the high-k insulating layer is formed using the ALD method. Accordingly, characteristics such as the dielectric constant, the leakage current, breakdown voltage, flatband voltage, and cycling can be improved, an excellent film quality and an excellent step coverage characteristic can be obtained, and an inter-cell interference phenomenon can be reduced. Consequently, devices with high performance and high reliability can be fabricated.

Third, since the high-k insulating layer is formed at low temperature of 500 degrees Celsius, thermal budget with respect to the underlying tunnel insulating layer can be decreased. Accordingly, reliability of devices can be improved.

Fourth, the insulating layers on and below the high-k insulating layers are formed from the aluminum oxide (Al₂O₃) layer. Accordingly, a reaction at the interface of the high-k insulating layer and the insulating layer is prohibited and a lowering of the dielectric constant of the high-k insulating layer can be prevented. Thus, the dielectric constant of the high-k layer can be further improved. Further, if the aluminum oxide (Al₂O₃) layer is deposited using the ALD method, the film quality and step coverage can be improved. If the aluminum oxide (Al₂O₃) layer and the high-k insulating layer are formed using an in-situ process, productivity can be enhanced.

Fifth, the nitrogen-containing insulating layers are formed on and below the high-k insulating layers, over the floating gate and under the control gate. A reaction at the interface of the respective layers can be prohibited and a lowering of the dielectric constant can be prevented. Therefore, although a sidewall oxidization process is performed on a gate sidewall in a subsequent process, a bird's beak phenomenon occurring at both edges of the polysilicon layer for the floating gate or the control gate can be prevented.

Sixth, the control gate is formed from the metal layer comprised of metal material with a work function. Accordingly, a reaction at the interface can be prohibited and the leakage current can be reduced.

The invention is not limited to the disclosed embodiment, but may be implemented in various manners. The embodiment is provided to complete the disclosure of the invention and to allow those having ordinary skill in the art to understand the scope of the invention. The scope of the invention is defined by the claims.

What is claimed is:

1. A non-volatile memory device, comprising:
a tunnel insulating layer formed on a semiconductor substrate;
a floating gate formed on the tunnel insulating layer;
a first nitrogen-containing insulating layer formed on the floating gate;
a first insulating layer formed on the first nitrogen-containing insulating layer;
a high dielectric (high-k) insulating layer formed over the first insulating layer;
a second insulating layer formed over the high-k insulating layer;
a second nitrogen-containing insulating layer formed on the second insulating layer; and
a control gate formed over the second nitrogen-containing insulating layer.

2. The non-volatile memory device of claim 1, wherein each of the first and second insulating comprises aluminum oxide (Al₂O₃).

3. The non-volatile memory device of claim 1, wherein the high-k insulating layer comprises a layer selected from the group consisting of (a) a single material layer comprising a high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BaₓSr₁₋ₓTiO₃ where x<1 (BST), and Pb[ZrₓTi₁₋ₓ]O₃ where 0<x<1 (PZT); (b) a mixed material layer comprising a mixture of Al₂O₃ and a material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT; and, (c) a laminated structure layer comprising at least one layer of Al₂O₃ alternately laminated with at least one layer of a material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT.

4. The non-volatile memory device of claim 1, wherein the control gate comprises a polysilicon layer or a metal layer made of metal material with a high work function.

5. The non-volatile memory device of claim 4, wherein the control gate further comprises a tungsten nitride (WN) layer and a tungsten (W) layer formed over the metal layer.

6. The non-volatile memory device of claim 1, further comprising a third nitrogen-containing insulating layer between the high-k insulating layer and the first insulating layer, and a fourth nitrogen-containing insulating layer between the high-k insulating layer and the second insulating layer.

7. A non-volatile memory device, comprising:
a tunnel insulating layer formed on a semiconductor substrate;
a floating gate formed on the tunnel insulating layer;
a first insulating layer formed over the floating gate;
a first nitrogen-containing insulating layer formed on the first insulating layer;
a high-k insulating layer formed over the first nitrogen-containing insulating layer;
a second nitrogen-containing insulating layer formed on the high-k insulating layer;
a second insulating layer the first insulating layer the second nitrogen-containing insulating layer; and
a control gate formed over the second insulating layer.

8. The non-volatile memory device of claim 7, wherein each of the first and second insulating layers comprises a dichlorosilane-High Temperature Oxide (DCS-HTO) layer.

9. The non-volatile memory device of claim 7, further comprising a third nitrogen-containing insulating layer between the floating gate and the first insulating layer, and a fourth nitrogen-containing insulating layer between the second insulating layer and the control gate.

10. A method of fabricating a non-volatile memory device, the method comprising:
providing a semiconductor substrate;
sequentially forming a tunnel insulating layer and a first conductive layer over the semiconductor substrate;
forming a first nitrogen-containing insulating layer formed on the first conductive layer;
forming a first insulating layer on the first nitrogen-containing insulating layer;
forming a high-k insulating layer over the first insulating layer;
forming a second insulating layer over the high-k insulating layer;
forming a second nitrogen-containing insulating layer on the second insulating layer; and
forming a second conductive layer on the second nitrogen-containing insulating layer.

11. The method of claim 10, further comprising:
forming a third nitrogen-containing insulating layer over the first insulating layer before forming the high-k insulating layer; and
forming a fourth nitrogen-containing insulating layer over the high-k insulating layer before forming the second insulating layer.

12. The method of claim 10, comprising forming each of the first and second nitrogen-containing insulating layers using a Plasma Nitrification (PN) process or an Atomic Layer Deposition (ALD) method.

13. The method of claim 11, comprising forming each of the third and fourth nitrogen-containing insulating layers is using a Plasma Nitrification (PN) process or an Atomic Layer Deposition (ALD) method.

14. The method of claim 10, comprising forming each of the first and second insulating layers from an aluminum oxide (Al₂O₃) layer.

15. The method of claim 14, comprising forming the aluminum oxide (Al₂O₃) layer using an Atomic Layer Deposition (ALD) method employing a metal organic source or a halide source as an aluminum precursor.

16. The method of claim 10, wherein the high-k insulating layer comprises a layer selected from the group consisting of (a) a single material layer comprising a high-k material selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BaₓSr₁₋ₓTiO₃ where x<1 (BST), and Pb[ZrₓTi₁₋ₓ]O₃ where 0<x<1 (PZT); (b) a mixed material layer comprising a mixture of Al₂O₃ and a material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT; and, (c) a laminated structure layer comprising at least one layer of Al₂O₃ alternately laminated with at least one layer of a material selected from the group consisting of HfO₂, ZrO₂, SiON, La₂O₃, Y₂O₃, TiO₂, CeO₂, N₂O₃, Ta₂O₅, BaTiO₃, SrTiO₃, BST, and PZT.

17. The method of claim 10, comprising forming the high-k insulating layer using an Atomic Layer Deposition (ALD) method employing a metal organic source or a halide source as a metal precursor.

18. The method of claim of claim 10, comprising further performing a thermal treatment process between forming the second nitrogen-containing insulating layer and forming the second conductive layer.

19. The method of claim of claim 11, comprising further performing a thermal treatment process between forming the fourth nitrogen-containing insulating layer and forming the second conductive layer.

20. The method of claim of claim 10, further comprising, after forming the second conductive layer:
forming a gate pattern having a sidewall by patterning the second conductive layer, the first and second nitrogen-containing insulating layers, the first and second insulating layers, the high-k insulating layer, the first conductive layer, and the tunnel insulating layer; and
forming a sidewall oxide layer on the sidewall of the gate pattern by performing a sidewall oxidization process.

21. A method of fabricating a non-volatile memory device, the method comprising:
providing a semiconductor substrate;
sequentially forming a tunnel insulating layer and a first conductive layer over the semiconductor substrate;
forming a first insulating layer over the first conductive layer;
forming a first nitrogen-containing insulating layer on the first insulating layer;
forming a high-k insulating layer over the first nitrogen-containing insulating layer;
forming a second nitrogen-containing insulating layer on the high-k insulating layer;
forming a second insulating layer over the second nitrogen-containing insulating layer; and
forming a second conductive layer over the second insulating layer.

22. The method of claim 21, further comprising:
forming a third nitrogen-containing insulating layer over the first conductive layer before forming the first insulating layer; and
forming a fourth nitrogen-containing insulating layer on the second insulating layer before forming the second conductive layer.

23. The method of claim 21, wherein each of the first and second insulating layers comprises a dichlorosilane-High Temperature Oxide (DCS-HTO) layer.
